(19) United States
(12) Patent Application Publication
(10) Pub. No.: US 2010/0207140 A1
(43) Pub. Date: Aug. 19, 2010

(54) COMPACT MOLDED LED MODULE

(75) Inventors: Serge Laurent RUDAZ, Sunnyvale, CA (US); Serge BIERHUIZEN, Santa Rosa, CA (US); Ashim Shatil HAQUE, Freemont, CA (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/388,525

(22) Filed: Feb. 19, 2009

(51) Int. Cl. H01L 33/00; H01L 21/50

(52) U.S. Cl. 257/98; 438/27; 257/E33.056; 257/E21.499

(57) ABSTRACT

A method of forming a light emitting diode (LED) module molds an array of lens support frames over an array of connected lead frames. LEDs are bonded to the lead frame contacts within the support frames. Molded lenses are then affixed over each support frame, and the lead frames are diced to create individual LED modules. In another embodiment, the lenses are molded along with the support frames to create unitary pieces, and the support frames are affixed to the lead frames in the array of connected lead frames. In another embodiment, no lenses are used, and cups are molded with the lead frames so that the LED module is formed solely of the unitary lead frame/cup and the LED. Since each LED enclosure is formed of only one or two separate pieces, and the modules are fabricated on an array scale, the modules can be made very small and simply.

### FIELD OF THE INVENTION

The present invention relates to methods of packaging light emitting diodes (LEDs) to form tiny modules and, in particular, to a fabrication technique for an LED module that uses very few parts.

### BACKGROUND OF THE INVENTION

Some digital cameras, such as those incorporated into cell phones, use LED flashes due to the small size of the flash module and the low voltage LED power supply. Such modules are typically substantially rectangular with dimensions of about 5×5 mm and 3 mm high. Such dimensions are the smallest practically achievable using the current module designs.

The modules are typically formed by molding plastic housings, then snapping metal leads onto the housings, then snapping molded lenses onto the tops of the housings, then providing an LED die mounted on an over-sized ceramic submount for each housing, then centering a housing over the LED die and submount, then soldering the housing leads to top pads on the submount, where the soldering also fixes the LED/submount to the housing to complete the module. The process is performed on individual units, so there is a lot of handling and many process steps. Such a module has very tight tolerances and, due to the number of individual parts, the module is relatively expensive to produce.

What is needed is a new design of an LED module that allows the module to be smaller and have fewer parts. What is also needed is an LED module design that can be fabricated with more relaxed tolerances, as well as be fabricated cheaper and faster than the prior art modules.

### SUMMARY OF THE INVENTION

An object of the invention is to provide an LED module and method of its manufacture that improve upon the prior art. Various embodiments are disclosed.

In one embodiment, a metal sheet of connected lead frames is used as an electrical interface between LEDs electrodes and a printed circuit board on which the LED modules will be eventually mounted. The array of flat lead frames is placed in a mold that also defines reflective tubs formed over each lead frame. A plastic is then molded by the mold to fill in voids in the array of lead frames and form the tubs as a unitary part. Encapsulated LEDs are then directly bonded to lead frame pads exposed on the top surface of the lead frames and within the reflective tubs. The sheet will typically contain hundreds of lead frames for the LEDs. Such array-scale processing is much simpler and faster than handling individual lead frames and separately molded tubs. The sheet is then diced, such as by breaking along scribe lines, to separate out the individual LED modules. Hundreds or thousands of LED modules may be formed simultaneously using this technique.

In another embodiment, a sheet of lead frames and lens support frames are molded as a unitary part. Preformed light-collecting lenses are then affixed over each support frame, and the sheet is then diced to separate out the LED modules.

In another embodiment, LEDs are bonded to a sheet of molded lead frames. Molded light-collecting lenses, with integral support frames, are then affixed over each LED on the sheet, and the sheet is then diced to separate out the LED modules.

Various structure and manufacturing details are also described. Since the manufacturing is on an array-scale, handling, positioning, and other processing are performed faster and with more accuracy. In the examples given, the module, excluding the LED, is either one or two parts. Since there are no requirements for any precisely matching fits, the manufacturing tolerances are relaxed. Further, the LED module can be made smaller than prior art modules, such as having a footprint of 2.5×3 mm or less and a height of 2.5 mm or less.

### BRIEF DESCRIPTION OF THE DRAWINGS

FIG. 1 is a cross-sectional view of a portion of a sheet of molded lead frames with reflective tubs.

FIG. 2 is a cross-sectional view of LEDs with submounts bonded to pads on the lead frames within the tubs of FIG. 1.

FIG. 3 is a flowchart describing the steps used to form the structure of FIG. 2.

FIG. 4 is a cross-sectional view of a portion of a sheet of molded lead frames with lens support frames.

FIG. 5 is a cross-sectional view of light-collecting lenses to be affixed to the support frames of FIG. 4.

FIG. 6 is a more detailed view of the lenses in FIG. 5.

FIG. 7 is a cross-sectional view of LEDs with submounts bonded to pads on the lead frames within the support frames of FIG. 4.

FIG. 8 is a cross-sectional view of the light-collecting lenses of FIG. 5 affixed to the support frames of FIG. 7.

FIG. 9 is a flowchart describing the steps used to form the structure of FIG. 8.

FIG. 10 is a cross-sectional view of a portion of a sheet of molded lead frames.

FIG. 11 is a cross-sectional view of LEDs with submounts bonded to pads on the lead frames of FIG. 10.

FIG. 12 is a cross-sectional view of light-collecting lenses and lens support frames, where each lens and support frame is of unitary construction, to be affixed to the lead frames of FIG. 11.

FIG. 13 is a more detailed view of the lens and support frame in FIG. 12.

FIG. 14 is a cross-sectional view of the unitary light-collecting lenses and support frames of FIG. 12 affixed to the lead frames of FIG. 11 for each LED.

FIG. 15 is a flowchart describing the steps used to form the structure of FIG. 14.

FIG. 16 is an example of a top down view of any of the modules, showing the LED in the middle, the light-collecting lens or reflective tub around the LED, and the module outer perimeter. The lens or tub may be circular, rectangular, hexagonal, or other suitable shape depending on the requirements of the light pattern.

FIG. 17 is an example of a bottom view of any of the modules showing the pads of the lead frame to be connected to a printed circuit board.

Elements in the various figures that are the same or equivalent are identified with the same numerals.

### DETAILED DESCRIPTION

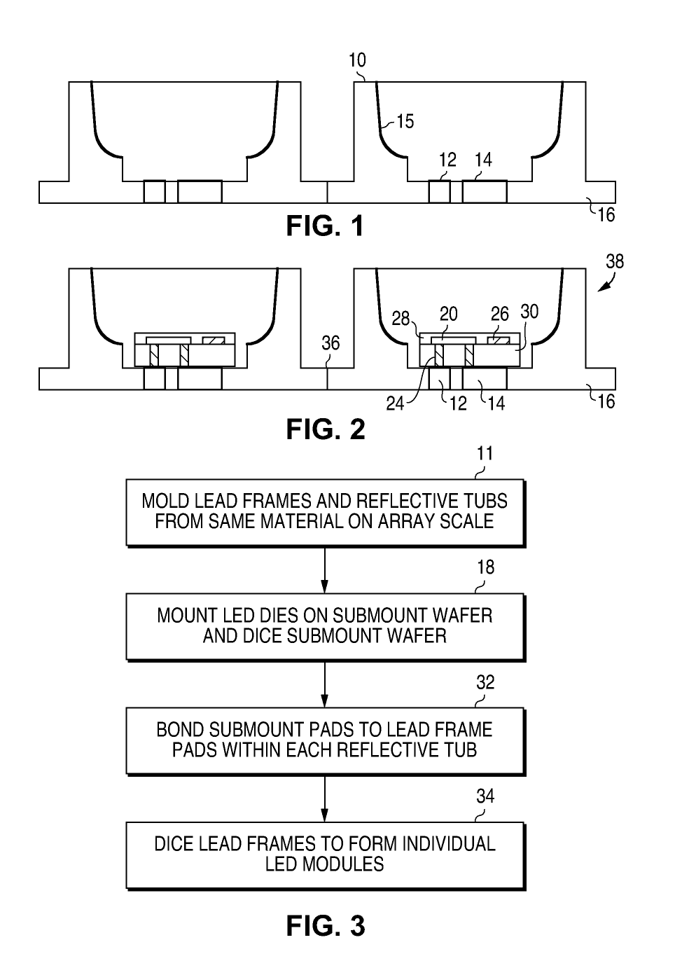

A process for forming a first embodiment of a compact LED module is shown in FIGS. 1 and 2 and summarized in the flowchart of FIG. 3.

A mold is created for receiving a thin metal sheet (e.g., 0.5 mm) of connected lead frames, such as formed of stamped or etched copper. The lead frames are customized for the LED modules by having metal pads in positions that align with corresponding pads of an LED submount. In another embodiment, a submount is not needed, and the LED die electrodes are bonded to the lead frame pads. Each lead frame for an LED needs at least an anode pad and a cathode pad. The metal pads are held in position within the copper lead frame by peripheral portions that are later cut during the dicing process, so the pads are ultimately electrically insulated from one another. In the lead frames used for the module, all pads for connection of the module to a printed circuit board are on the bottom surface of the module.

Metal lead frames are well known, and it is within the skill of one skilled in the art to pattern a lead frame to meet the requirements of the inventive module.

The mold has cavities defining the tubs 10 in FIG. 1. The tubs may be on the order of 2 mm high, since the LEDs are very small and thin. An LED may have sides less than 1 mm. Molding processes using a softened or liquid molding material are well known.

In step 11 of FIG. 3, the metal lead frame sheet is positioned in the mold, and a softened or liquid plastic fills in the mold to form the tubs 10 and fills in the voids in the lead frame sheet. The plastic may be Zytel™ by Dupont, or any high-temperature plastic suitable for molding. A high-temperature plastic is defined herein as any compound capable of withstanding the standard lead-free industrial solder reflow assembly processes without deformation or damage significant enough to compromise the mechanical and optical integrity needed for the LED module's operation. The mold may be first filled with the softened plastic prior to placing the lead frame sheet in the mold, or the plastic may be injection molded after the sheet is placed in the mold. The plastic is then cured and the structure is removed from the mold. The entire height of the molded structure may be less than 3 mm. Although FIG. 1 only shows two tubs over their associated lead frames, the sheet contains a two-dimensional array of tubs and lead frames, which would typically exceed a thousand tubs and lead frames for a high throughput.

Lead frame pads 12 and 14 are shown extending between the top and bottom surfaces of the molded lead frame 16. The molded lead frames and tubs of FIG. 1 form a unitary part so it can be easily handled as a unit by conventional automatic positioning equipment.

If the molded plastic forming the tubs 10 is sufficiently reflective, such as a diffusing white color, then no reflective coating in needed for the tub walls. If a reflective coating is needed, the lead frame pads can be masked, and the reflective coating 15 can be deposited on the tub walls. Spray-on and vacuum-deposited reflective coatings are well known.

In step 18, conventional LEDs are formed and mounted on submounts. The LED die 20, shown in FIG. 2 may be a GaN blue-emitting die coated with a YAG phosphor (emits yellow-green) or coated with red and green phosphors. The blue light leaking through the phosphor combined with the light emitted by the phosphor creates white light. Such white light LEDs are well known. The LED die 20 is formed as a flip-chip with both electrodes on the bottom. The LED die 20 is bonded to corresponding pads of a submount wafer along with many other LED dies bonded to corresponding pads of the same submount wafer. The wafer may be ceramic with electrodes 24 extending between the top and bottom surfaces of the submount wafer. Submounts for LEDs are well known. ESD protection chips 26 may also be mounted on the submount wafer for ESD protection of each LED die 20. The LED dies and ESD protection chips are encapsulated by, for example, silicone 28. The wafer is then diced to separate out the LEDs/submounts. A single submount is identified as submount 30 in FIG. 2.

The total thickness of the LED die 20 and submount 30 may be on the order of 1 mm or less.

In step 32, the submount pads are ultrasonically welded to the corresponding pads of the lead frame 16 within each tub 10. If desired, the lead frame pads may have a layer of gold, nickel, or other suitable material to promote the welding or soldering. Such coating and welding techniques are well known.

In step 34, the lead frame sheet is diced, such as along the line 36 in FIG. 2, to separate out the individual LED modules 38. The lead frame sheet may include preformed notches or microperforations defining the grid along where the lead frames are to be separated. The dicing may be performed by a simple breaking of the lead frames along the notches or microperforations.

Since the process for forming the LED modules 38 is performed on an array scale, the process is relatively easy, fast, inexpensive, and efficient. No lens is needed since the encapsulant protects the LED die, and the emitted beam may be shaped by the shape of the tub 10. A circular tub will form a substantially circular beam. A rectangular tub will form a generally rectangular beam. In one embodiment, the tub is hexagonal. The module 38, excluding the LED, is only a single molded piece.

In one embodiment, each module 38 footprint is about 2.5×3 mm, with a height less than 3 mm.

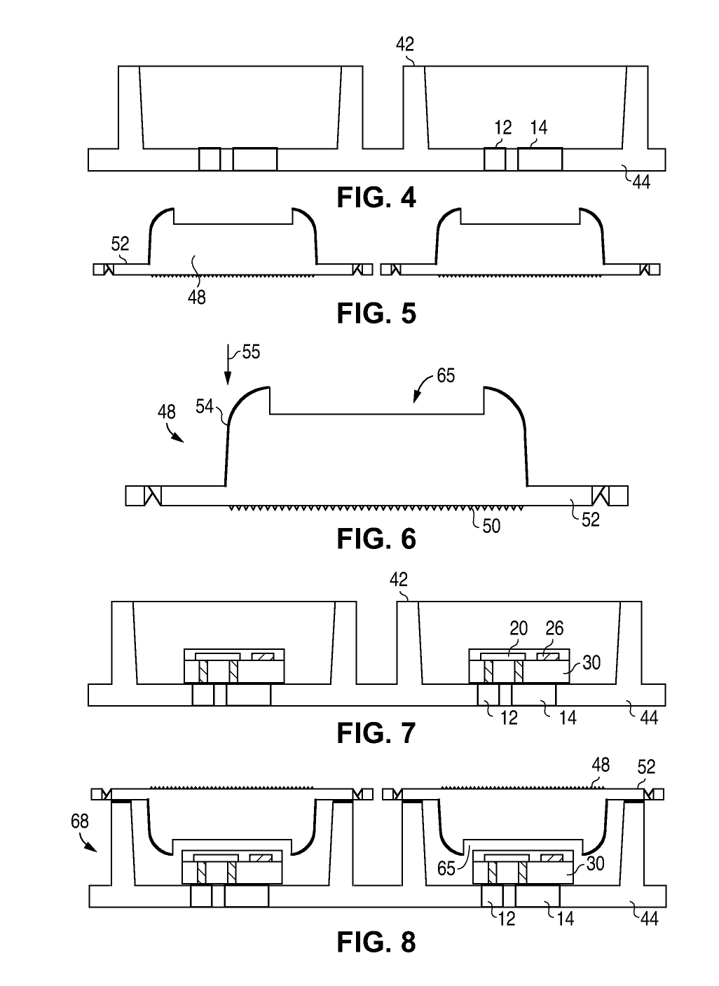

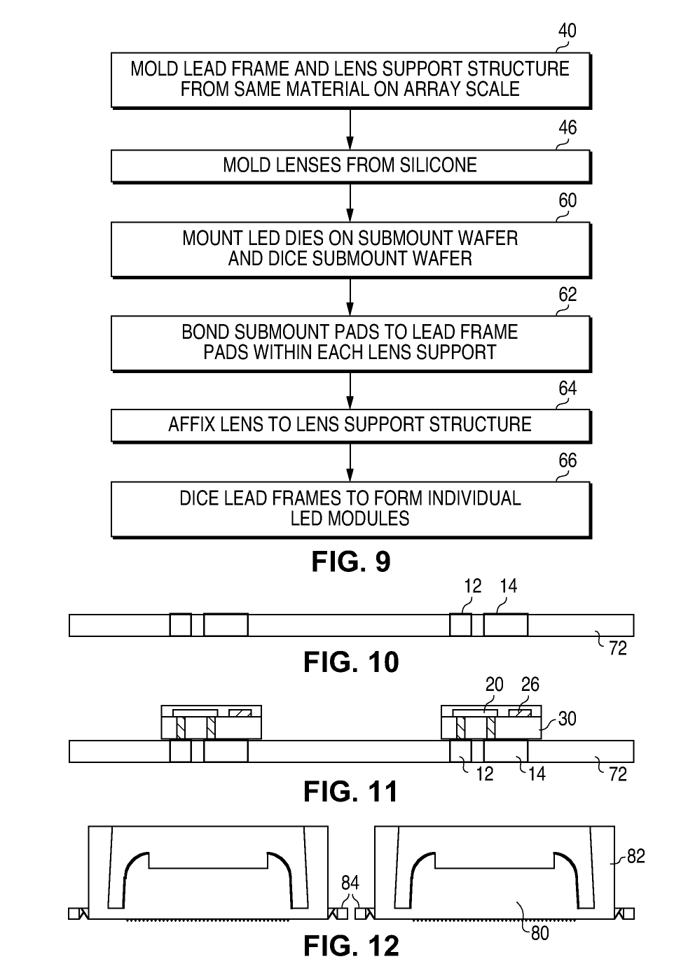

FIGS. 4-8 illustrate another embodiment, and the flowchart of FIG. 9 summarizes the fabrication process.

In step 40 of FIG. 9, a copper lead frame sheet, similar to the lead frame sheet discussed with respect to FIG. 1, is placed in a mold that defines the lens support frame 42 shown in FIG. 4. The molding process and plastic may be the same as discussed with respect to FIG. 1. The total height may be between 2-3 mm. The molding process forms the molded lead frame 44 and the support frame 42 as a unitary part for subsequent array-scale processing.

In step 46, light-confining lenses 48 (FIG. 5) are molded from, for example, a high index of refraction silicone. The molding material for the lenses 48 is limited since the material must remain substantially transparent despite the high light intensity and heat from the fabrication process of the LED module and its assembly in the customer's product. However, the molding material for the lead frame 44 and support frame 42 may be a wide variety of less expensive, mechanically stiffer, not necessarily transparent, high-temperature materials (e.g., Zytel™), so will typically not be the relatively expensive silicone. The lenses 48 may be formed connected to each other after molding and broken along predetermine break lines to separate out the lenses 48. This may be done by a positioning machine immediately before affixing the lenses 48 to the support frames 42 to simplify handling.

FIG. 6 is a more detailed view of the lens 48. The light emitting side of the lens 48 is shown molded to have optical features for shaping the light and/or improving light output coupling (reducing total internal reflection). The lens 48 is shown having a pattern of small concentric rings of prisms 50 to create a Fresnel lens for shaping the light pattern. For other designs, such as for general illumination, the light emitting surface may be randomly roughened to output a wide uniform beam. The lens 48 has a flange 52 for affixing to the top of the support frame 42, such as by gluing. In one embodiment, the support frame 42 and lens 48 may be formed to have interconnecting tabs, notches, or clips so the parts can be snapped together.

To collect the light from the LED and direct the light out of the lens 48, a reflective coating 54 may be deposited on the lens 48. This may be done while the lenses 48 are connected together to simplify handling. In one embodiment, the coating is specular so the light is reflected toward the output surface of the lens 48. Arrow 55 represents a reflective material being deposited over the outer surface of the lens 48 except for the light entrance surface. In another embodiment, a reflective coating is not needed if sufficient reflection is accomplished with total internal reflection (TIR).

In step 60 of FIG. 9, the LED dies 20 are mounted on a submount wafer, as discussed with respect to FIG. 2, and the wafer is diced to separate out the LEDs.

In step 62, as shown in FIG. 7, the bottom pads of the submounts 30 are bonded to corresponding pads of the lead frame 44, such as by ultrasonic welding. Such bonding is performed on an array scale for more efficient processing.

In step 64, the lenses 48 are affixed to the support frames 42, as shown in FIG. 8, by, for example, glue or other means. In one embodiment, the lenses 48 are individually handled and positioned. In another embodiment, the lenses 48 are connected together and placed over the support frames 42 together, where the lenses 48 will be separated at the same time that the lead frames 44 are separated, such as be sawing or breaking.

The positioning tolerances are relaxed since the vertical height of the lens 48 over the LED die 20 is determined by the mold, and the lateral positioning is not critical. The air gap between the LED die encapsulant and the lens 48 may be as little as 0.1 mm. Virtually all light emitted from the LED die 20 will be coupled into the lens 48 with little reflection since the input surface of the lens 48 is parallel with, and close to, the top surface of the LED die 20, and the LED die 20 is positioned within a cavity 65 of the lens 48 to capture light throughout a 180° angle. The cavity 65 allows the module to be very shallow, since the outer part of the lens 48 can be below the surface of the LED die 20 without the lens contacting the LED.

In step 66, the lead frames 44 are diced to form individual LED modules 68.

In one embodiment, each module 68 footprint is about 2.5×3 mm, with a height less than 3 mm.

FIGS. 10-14 illustrate another embodiment, and the flowchart of FIG. 15 summarizes the fabrication process.

In step 70 of FIG. 15, a copper lead frame sheet, similar to the lead frame sheet discussed with respect to FIG. 1, is placed in a mold or otherwise processed to fill the voids in the lead frame with plastic. This adds rigidity to the lead frame 72 (FIG. 10) and seals the bottom of the module, as with the other embodiments. No support frame or tub is molded with the lead frame 72.

In step 74, as in step 18 of FIG. 3, the LED dies 20 are mounted on submounts 30.

In step 76, the submount 30 pads are ultrasonically welded to the lead frame pads 12 and 14, as shown in FIG. 11.

In step 78, silicone lenses 80 (FIG. 12) along with a lens support frame 82 are molded as a unitary part. All lenses/frames may be connected together (at the flanges 84) after the molding process so they can be affixed to the lead frame 72 together in a single operation, or the lenses/frames can be individually handled.

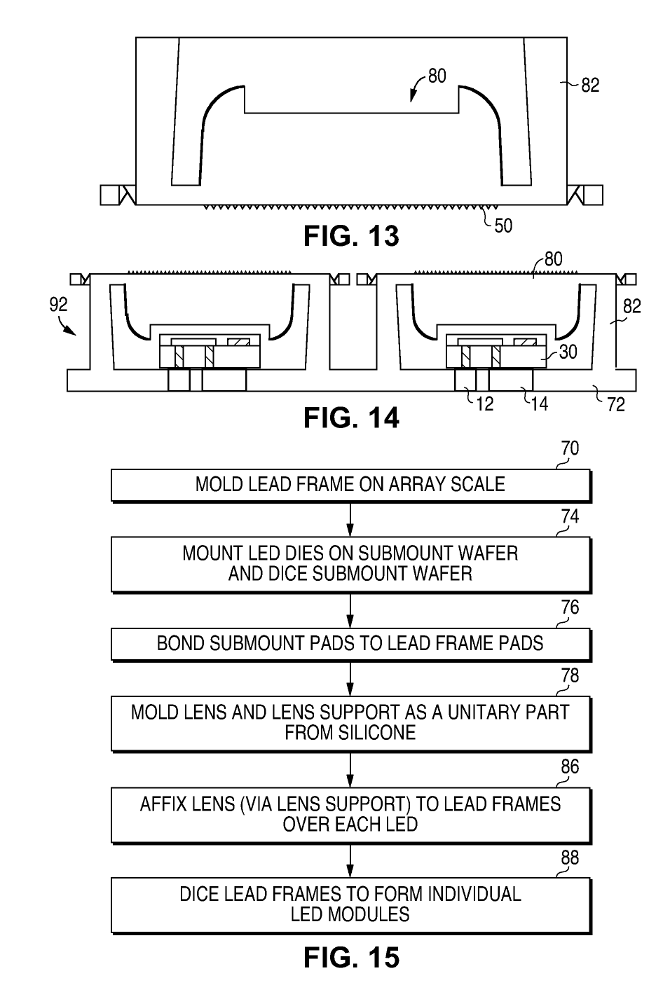

FIG. 13 illustrates the lens 80 and support frame 82 in more detail. The lens 80 may be the same as the lens 48 shown in FIG. 6.

In step 86, as shown in FIG. 14, the support frames 82 are affixed to the lead frame 72 so that the lens 80 overlies each LED die 20. Glue or other means may be use.

In step 88, the lead frames 72 are diced to form individual LED modules 92.

In one embodiment, each module 92 footprint is about 2.5×3 mm, with a height less than 3 mm.

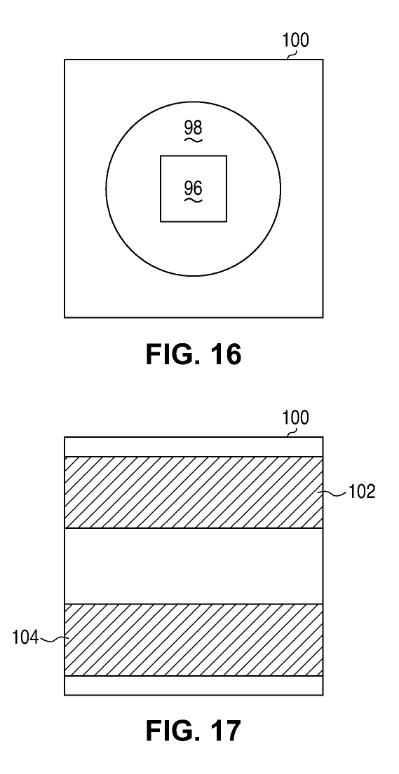

FIG. 16 is a top down view of any of the modules described above, showing the LED/submount 96 in the middle, the light-collecting lens or reflective tub 98 around the LED/submount 96, and the module outer perimeter 100 defined by the outer perimeter of the molded lead frame after dicing. The lens and/or tub may be rectangular, elliptical, hexagonal, or other suitable shape depending on the requirements of the light pattern.

As in all embodiments, a submount is not necessary since the flip-chip LED die electrodes may be directly bonded to the lead frame top pads. The copper lead frame contact areas may be coated with a gold layer to enable ultrasonic welding of the LED electrodes to the lead frame. Since the LED die can be thinner than 250 microns, the resulting module can be significantly less than 3 mm high, such as even 1.5-2.5 mm. In all embodiments, the LED die or submount may be soldered to the lead frame rather than ultrasonically welded. As used herein, the term LED includes either a bare LED die or an LED die mounted on a submount.

FIG. 17 is a bottom view of any of the modules showing the anode and cathode pads 102 and 104 of the lead frame, to be connected to a printed circuit board. Any pattern of pads may be used. The pads 102 and 104 are just opposite surfaces of the upper pads 12 and 14 shown in the various figures.

The LED modules may be used for camera flashes, general lighting where a small size is desired, or for any other application. Any type of LED may be used to create any pattern and color of light.

The modules described herein are formed with only a few parts, and functional pieces are molded together to form a unitary part for array-scale processing, so some or all processes are formed simultaneously on many hundreds of LED modules at the same time to increase processing speed, reduce cost, ease handling, increase consistency, and to achieve other advantages. In the various modules described, there are no precise positioning steps required to achieve tight performance specifications.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A method of forming a light emitting diode (LED) module comprising:
providing an array of connected lead frames, the lead frames having a top surface and a bottom surface, the lead frames having top metal contacts for electrical connection to LEDs;
molding support frames for supporting lenses;
molding lenses;
attaching LEDs to the top metal contacts of the lead frames;
affixing the lenses over the LEDs such that the lenses are supported over the LEDs by the support frames; and
dicing the lead frames to create individual LED modules, each module containing a single lead frame, a single lens, and a single support frame, the support frame forming outer walls of each module, and the lead frame forming a bottom surface of each module, with the bottom surface having bottom metal contacts.

2. The method of claim 1 further comprising:
molding a first material around the array of connected lead frames and, at the same time, molding the first material to form the support frames over the lead frames to form a unitary part comprising a molded array of connected lead frames and a molded array of support frames, each support frame being associated with a different lead frame;
wherein molding the lenses comprises molding the lenses separately from the support frames, the lenses being molded with a second material different from the first material; and
wherein affixing the lenses over the LEDs comprises affixing the lenses over the support frames.

3. The method of claim 2 wherein the second material comprises transparent silicone.

4. The method of claim 2 wherein the support frames are less than 3 mm high.

5. The method of claim 2 wherein each lens has a flange, wherein affixing the lenses over the LEDs comprises affixing the flange of each lens to a top of a support frame.

6. The method of claim 1 wherein the bottom surface of each lead frame, after dicing, defines a footprint of each module.

7. The method of claim 1 wherein each of the lenses has a cavity, and affixing the lenses over the LEDs comprises affixing the lenses so that light from the LEDs enters the cavity.

8. The method of claim 1 further comprising depositing a reflective coating over a portion of an outer surface of the lenses that reflects light upward through an exit surface of the lenses.

9. The method of claim 1 wherein molding the support frames for supporting lenses and molding the lenses comprise molding the support frames and lenses together with the same material so that each support frame and its associated lens is a unitary part after dicing, wherein affixing the lenses over the LEDs comprises affixing each support frame to a lead frame in the array of connected lead frames.

10. A light emitting diode (LED) module comprising:
a molded lead frame having a top surface and a bottom surface, the lead frame having top metal contacts for electrical connection to an LED;
a molded support frame for supporting lenses;
a molded lens,
wherein the support frame is molded along with the lead frame to form a unitary piece molded of the same material, or the support frame is molded along with the lens to form a unitary piece of the same material; and
an LED attached to the top metal contacts of the lead frame;
wherein the lens is affixed over the LED such that the lens is supported over the LED by the support frame, such that the entire LED module, excluding the LED, is formed by two molded pieces.

11. The LED module of claim 10 wherein the LED comprises an LED die mounted on a submount, wherein contacts on the submount are electrically connected to the metal contacts of the lead frame.

12. The LED module of claim 10 wherein the support frame is molded along with the lead frame to form a unitary piece molded of the same material.

13. The LED module of claim 10 wherein the support frame is molded along with the lens to form a unitary piece of the same material.

14. The LED module of claim 10 wherein the lens comprises a cavity, and the lens is affixed over the LED so that light from the LEDs enters the cavity, the lens comprising a reflective layer over an outer surface of the lens.

15. A method of forming a light emitting diode (LED) module comprising:
providing an array of connected lead frames, the lead frames having a top surface and a bottom surface, the lead frames having top metal contacts for electrical connection to LEDs;
molding a first material around the array of connected lead frames and, at the same time, molding the first material to form cups over the lead frames for surrounding each LED, each cup being associated with a different lead frame;
attaching LEDs to the top metal contacts of the lead frames within each cup; and
dicing the lead frames to create individual LED modules, each module containing a single lead frame molded with the cup, and a single LED, with no lens, and the lead frame forming a bottom surface of each module, with the bottom surface having bottom metal contacts.
